(19) United States
(12) Patent Application Publication
(10) Pub. No.: US 2022/0080412 A1
(43) Pub. Date: Mar. 17, 2022

(54) PROCESS FOR MANUFACTURING A MICRO-FLUIDIC DEVICE AND DEVICE MANUFACTURED USING SAID PROCESS

(71) Applicant: Commissariat à l'Energie Atomique et aux Energies Alternatives, Paris (FR)

(72) Inventors: Olivier CONSTANTIN, Grenoble Cedex 09 (FR); François BALERAS, Grenoble Cedex 09 (FR); Thibault FRESNEAU, Grenoble Cedex 09 (FR); Nicolas VERPLANCK, Grenoble Cedex 09 (FR)

(73) Assignee: Commissariat à l'Energie Atomique et aux Energies Alternatives, Paris (FR)

(21) Appl. No.: 17/447,822

(22) Filed: Sep. 16, 2021

(30) Foreign Application Priority Data
Sep. 17, 2020 (FR) 20 09399

(51) Int. Cl. B01L 3/00; B81C 1/00

(52) U.S. Cl. CPC B01L 3/502707; B81B 2201/058; B01L 2200/12; B81C 1/00119

(57) ABSTRACT

A process for manufacturing a micro-fluidic device, the device including a substrate made of thermoplastic polymer having a face called the upper face and a first micro-fluidic circuit that includes at least one aperture that opens onto the upper face, and a component bearing pads arranged to become anchored in the substrate on the periphery of the aperture, the process including the following steps: heating so that the anchoring pads of the component reach a temperature at least equal to the glass-transition temperature of the substrate; fastening the component to the substrate by embedding then anchoring its pads in the substrate.

### TECHNICAL FIELD OF THE INVENTION

The present invention relates to a process for manufacturing a micro-fluidic device and to the micro-fluidic device obtained using the process.

### PRIOR ART

Micro-fluidics has more and more applications. One thereof notably concerns labs on chips and autonomous analysing microsystems. These applications may require sensors or imagers to be integrated into a micro-fluidic substrate, with a view to monitoring in real time and as closely as possible the sample present in the substrate. However, sensors are often produced in technologies different from those employed for the substrate and that are not always compatible. As a result, it is necessary to ensure that the technology used to hybridize sensors and substrate produces systems that are seal-tight, closed, functional both fluidically and electrically, easy to connect to the exterior as regards the delivery of fluid and the redistribution of electrical contacts, and lastly biocompatible.

Currently, devices are often composed of a micro-fluidic substrate, produced in the form of a board, and of a component produced on a silicon or glass substrate and having a particular functionality. The component is often fastened to the substrate by bonding, this possibly proving to be incompatible with the fluidic process (presence of solvent, unwanted adsorption of biological molecules, lack of biocompatibility, etc.) or leading to the formation of disadvantageous dead volumes. Other methods for achieving micro-fluidic integration of components have been described in the prior art. By way of example, the component may also be fastened magnetically, but this requires seals to be provided, and these are not easy to fit and do not guarantee a durable seal-tightness.

Lastly, known techniques often do not allow a high manufacturing rate to be obtained.

Patent application WO2011/042422A1 describes a method for joining two microfluidic elements

Document DE102016226198A1 for its part describes a way of joining a component bearing anchoring pads to a substrate.

The aim of the invention is to provide a solution that allows a component to be joined to a micro-fluidic substrate with a view to obtaining a fluidic seal-tightness and, optionally, an electrical connection between these two portions and that:
is simple to implement;
is of a moderate cost;
does not require the provision of a substance such as an adhesive and/or solvent, or of additional elements such as seals;
allows a high manufacturing rate to be achieved;
is capable of easy industrial transfer, in that it employs existing techniques.

### DISCLOSURE OF THE INVENTION

This aim is achieved by a process for manufacturing a micro-fluidic device, said device comprising a substrate made of thermoplastic polymer having a face called the upper face and a first micro-fluidic circuit that comprises at least one aperture that opens onto said upper face, and a component bearing pads arranged to become anchored in said substrate on the periphery of said aperture, said process comprising the following steps:
heating so that the anchoring pads of the component reach a temperature at least equal to the glass-transition temperature of the substrate;
fastening the component to the substrate by embedding then anchoring its pads in the substrate.

According to one particularity, the process comprises a prior step of creating holes in the substrate, these holes each being configured to receive one separate pad of the component, with a view to facilitating the embedment of each pad of the component in the fastening step.

The invention also relates to a micro-fluidic device comprising a substrate made of thermoplastic polymer having a face called the upper face and a first micro-fluidic circuit that comprises at least one aperture that opens onto said upper face, and a component bearing pads arranged to become anchored in said substrate on the periphery of said aperture, said device being obtained using the manufacturing process such as defined above.

According to one particularity, the substrate is made of cyclic olefin copolymer.

According to one particularity, the component is produced on a silicon-on-glass substrate.

According to one particularity, the anchoring pads comprise at least one first pad made at least partially from metal.

According to one variant embodiment, the substrate comprises a first electrical circuit and the component comprises a second electrical circuit, said first pad being configured to make an electrical connection between the first electrical circuit and the second electrical circuit.

According to one particularity, the metal is composed of copper or of an alloy of SnAg type.

According to one particularity, the anchoring pads comprise one or more anchoring pads made of silicon.

According to one particularity, the anchoring pads have at their free end a rounded dome or a planar face.

According to one particular embodiment, the substrate comprises holes that are each configured to receive one separate pad of the component, said holes being produced with a view to facilitating the embedment of each pad of the component.

According to one particularity, the component is applied, via a face called the lower face, against the upper face of the substrate and sealed to the substrate by way of said anchoring pads, and the component is sealed in order to close the aperture of the first fluidic circuit in a seal-tight manner, on the upper face of the substrate.

According to one particular embodiment, the aperture of the first fluidic circuit takes the form of a channel the upper side of which is closed by the lower face of said component.

According to one particular embodiment, the component comprises a second micro-fluidic circuit, said component being positioned on the substrate in order to ensure a seal-tight fluidic link between the first micro-fluidic circuit of the substrate and the second micro-fluidic circuit of the component.

According to one particularity, the second micro-fluidic circuit of the component comprises a micro-fluidic channel configured to ensure a seal-tight link between two apertures of the first fluidic circuit.

According to another particularity, the component also comprises at least one row of pads arranged to anchor in said substrate and placed to form a peripheral bead for consolidating the attachment of the component to the substrate.

### BRIEF DESCRIPTION OF THE FIGURES

Other features and advantages will become apparent in the following detailed description that is provided with reference to the appended drawings, in which:

FIG. 1 shows the various steps of the process for manufacturing a micro-fluidic device, according to the invention; each step is illustrated by a view in perspective and a cross-sectional view.

FIGS. 2A, 2B, 2C, 2D, 2E show, seen in cross section, a plurality of variant embodiments of a micro-fluidic device able to be obtained using the process of the invention.

FIG. 3 shows a plurality of variant embodiments of the anchoring pads of the component.

FIGS. 4A and 4B show, seen from above, two variant embodiments of the fluidic aperture that is present in the substrate.

FIG. 5 shows, seen in cross section, a plurality of configurations in which the component is fastened to the substrate.

FIG. 6 shows a plurality of architectures of the component and illustrates the various parameters of the component that it is possible to adjust to achieve the various configurations shown in FIG. 5.

### DETAILED DESCRIPTION OF AT LEAST ONE EMBODIMENT

In the rest of the description, the terms “top”, “bottom”, “lower” and “upper” are to be understood with reference to an axis (X) drawn vertically on the page.

The invention notably relates to a process for manufacturing a micro-fluidic device that solely comprises a micro-fluidic substrate 1 and a component 2 intended to be fastened to the substrate. The component may have various features and functions (that may be passive (physical filter) or active (sensor, actuator)).

The component is joined to the substrate in a seal-tight manner without employing substances such as adhesive and/or solvent, or additional elements.

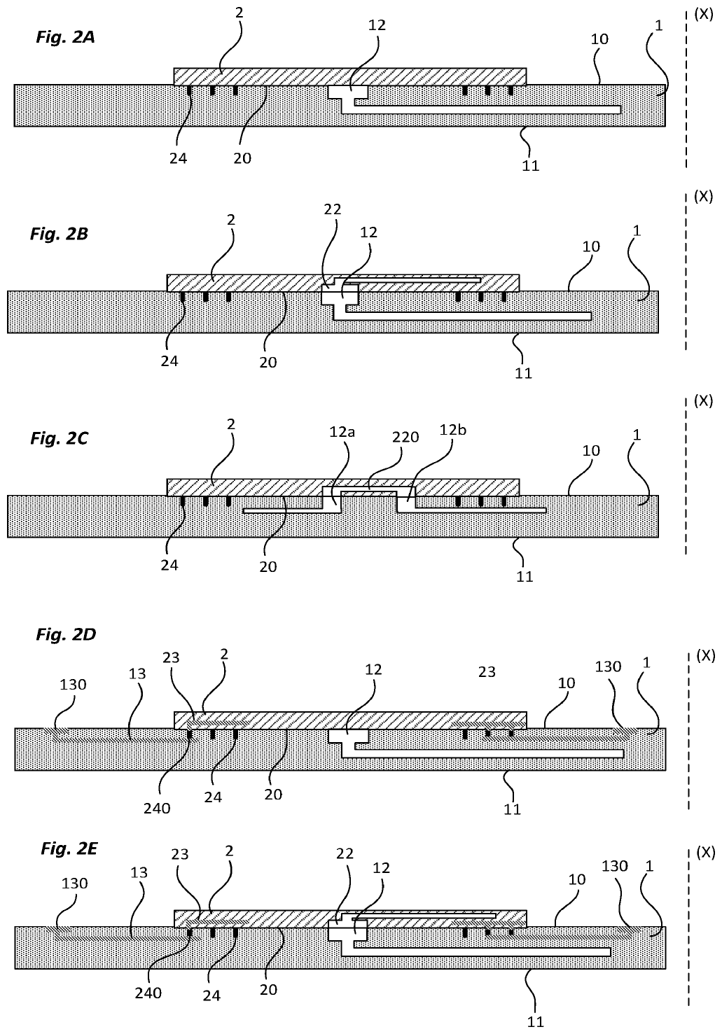

FIGS. 2A to 2E show various variant embodiments of the obtained micro-fluidic device.

The substrate 1 may be made of a thermoplastic polymer. By way of example, it may be a question of a cyclic olefin copolymer (COC) or of polymethyl methacrylate (PMMA).

The substrate 1 may take the form of a board having an upper face 10 and an opposite lower face 11.

The substrate 1 comprises a first micro-fluidic circuit. This first micro-fluidic circuit may be of any type. By way of example, it may comprise one or more cavities and micro-fluidic channels. It comprises at least one aperture 12 that opens onto a face of the substrate, its upper face 10 for example.

The substrate 1 may also comprise, in addition to the first micro-fluidic circuit, a first electrical circuit comprising one or more electrical tracks 13 and one or more electrical connection points 130 (FIGS. 2D and 2E) allowing the first electrical circuit to be connected to an external system.

The component 2 to be fastened to the substrate 1 may mainly be produced on a silicon-on-glass substrate.

It is intended to be fastened to a face of the substrate, its upper face 10 for example.

The shape of the component 2 is advantageously such that it has at least one planar face, called the lower face 20, intended to bear against the corresponding face of the substrate, the upper face 10 for example.

The component 2 may be intended to plug in a seal-tight manner (at least the aperture 12 of) the first micro-fluidic circuit of the substrate.

The component 2 may comprise a second micro-fluidic circuit, which may for example comprise an aperture 22 opening onto its lower face 20 and channels. The component 2 may then be fastened to the substrate in order to produce a seal-tight fluidic connection between the first micro-fluidic circuit of the substrate and the second micro-fluidic circuit of the component (FIGS. 2B, 2C and 2E). In FIG. 2B, the micro-fluidic circuit of the component 2 may comprise a channel 220 arranged to form a fluidic junction or bridge between two fluidic points 12a, 12b of the micro-fluidic circuit of the substrate 1.

The component 2 may comprise a second electrical circuit (FIGS. 2D and 2E) intended to be connected to the first electrical circuit of the substrate. This second electrical circuit may comprise one or more electrical tracks 23.

It will be understood that any combination of the presence of micro-fluidic circuits in the component and/or in the substrate and of the presence of electrical circuits in the component and/or in the substrate is of course producible.

To be fastened to the substrate 1, the component 2 comprises a plurality of pads 24 that allow it to anchor in the substrate 1.

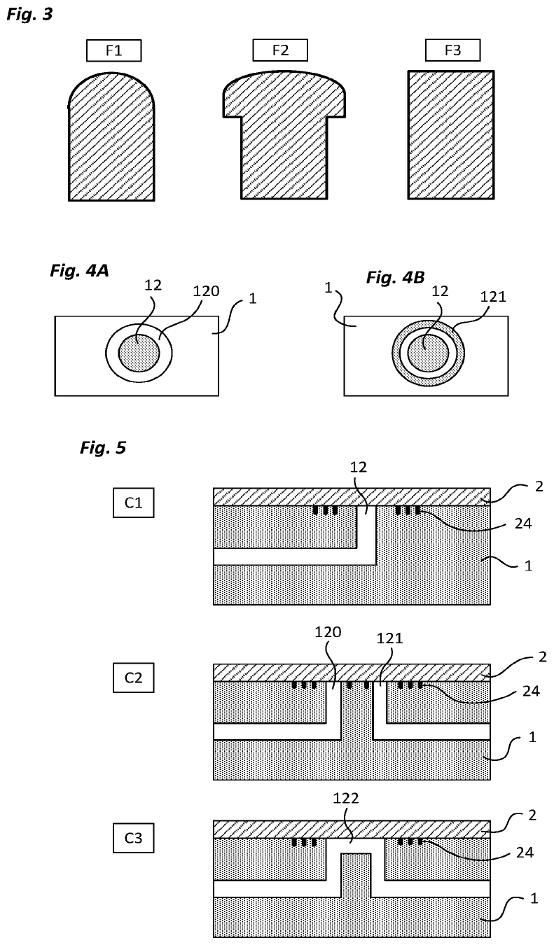

Non-limitingly, with reference to FIG. 3, the pads 24 may be the shape of a shell (i.e. a large-calibre projectile) (F1), of a mushroom (F2) or of a cylindrical pillar (F3).

The pads may be of various natures. It may be a question of silicon pads 24 formed by under etching a silica plinth or via a succession of anisotropic and isotropic etches, of micro-pillars obtained by deep etching, or even of micro-bumps i.e. metal pads (see below).

The size and shape of the pads 24 may be optimized to ensure the component 2 fastens to and is held fast by the substrate 1, while at least guaranteeing a seal-tightness of the fluidic circuit between the substrate 1 and the component 2.

Non-limitingly, the pads 24 may have a height comprised between 20 and 40 μm, and a diameter comprised between 20 and 50 μm.

The pads 24 may be organized into various configurations, in order to take into account the architecture of the micro-fluidic circuit of the substrate. In the case of a circular aperture to be closed from above or to be connected, the pads may be organized into a plurality of concentric rings. They may also be organized into a plurality of lines (rows or columns) and follow the outline of the micro-fluidic region in question. From one line to the next, the pads 24 may be aligned or staggered.

They may be spaced apart by a distance comprised between 20 and 50 μm, within each line and/or from one line to the next.

One or more rows of pads 24 will possibly be placed in other locations in order to consolidate the joint between the substrate 1 and the component 2.

At least one of the pads (referenced 240 in the figures) may also comprise at least one portion made of an electrically conductive metal forming an electrical connection point of the electrical circuit of the aforementioned component, if said circuit is present. A plurality of pads 240 of this type may be present and judiciously positioned. Each pad 240 may advantageously be made entirely of metal, and for example take the form of a micro-bump. The electrically conductive material employed in each of these pads 240 may be copper or an alloy of Sn/Ag type.

Via each of these pads 240, the electrical circuit of the component may be connected to the electrical circuit of the substrate 1. One electrical track may allow the metal portion of the pad to be connected to the electrical circuit of the component for the purposes of contact redistribution.

In the substrate 1, for each electrical connection point, a hole may be produced in a conductive track of the electrical circuit of the substrate in order to accommodate or at the very least facilitate the insertion of the corresponding connection pad of the component.

It will be noted that these electrical connection pads 240 are anchored in the substrate 1 in a similar way to the other pads 24 of the component 2.

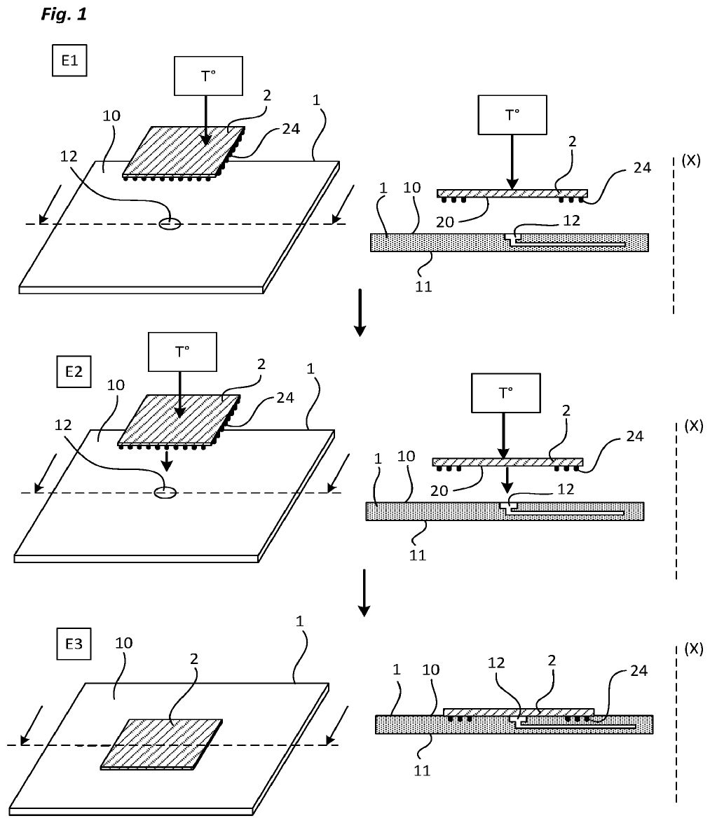

Starting with a substrate such as described above and with a component to be joined to said substrate, FIG. 1 shows the various manufacturing steps (E1 to E3) of the device:

E1: It is a question of a heating step (T°) allowing the pads 24 of the component 2 to be heated so that they reach a temperature at least equal to the glass-transition temperature (commonly called Tg) of the thermoplastic polymer from which the substrate 1 is made. By way of example, for a substrate based on 5013 COC, the temperature Tg is equal to 134° C. The temperature to which the pads are heated must also not be too high, in order to avoid any deterioration of the substrate and of its micro-fluidic circuit.

The heating may be carried out in various ways. By way of example, it is possible to employ a piece of equipment conventionally used for surface mounting electronic components. This type of equipment may notably allow only the component to be joined to be heated. It also has the advantage of being widely used in the industry, facilitating the technological transfer of the process proportionally.

Beforehand, holes may be preformed in the substrate 1 in the locations intended to receive the pads 24, in order to facilitate the embedment of the pads 24 in the substrate 1.

E2: It is a question of the step of fastening the component to the substrate. This is achieved by applying the lower face 20 of the component 2 against the upper face 10 of the substrate 1.

By virtue of the heating of the pads 24 to the temperature at least equal to the glass-transition temperature of the substrate 1, the component is compressed against the substrate 1, its lower face 20 against the upper face 10 of the substrate 1, so that its pads 24 embed in the material of the substrate. As the polymer from which the substrate is formed melts locally, it surrounds the pads and traps them when it cools, anchoring the component 2 in the substrate 1 and holding it fast to the substrate 1. It will be noted that the heating (T°) may continue into the step E2, in order to keep the pads at a suitable temperature (above Tg) and to facilitate their penetration into the substrate 1 when the component 2 is pressed against the substrate. The heating may be carried out in an identical way to that described with respect to step E1.

This way of fastening the component to the substrate allows a seal-tight link to be achieved in the plane of junction between the component and the substrate, irrespectively of whether it is for the purposes of plugging at least one aperture 12 of the first micro-fluidic circuit of the substrate, or of ensuring a seal-tight fluidic connection between the first micro-fluidic circuit of the substrate 1 and the second micro-fluidic circuit of the component 2. This link is produced without providing any additional elements or substance.

It will be noted that it is also possible to use ultrasound to enhance the thermo-compressive sealing action, in order to accelerate the placement of the component on the substrate and/or to decrease the thermal budget of the heating step. In all cases, it is a question of making it so that the pads 24 reach a temperature at least equal to the glass-transition temperature of the thermoplastic polymer from which the substrate is formed.

In the case of production of a seal-tight fluidic connection between the first micro-fluidic circuit of the substrate 1 and the second micro-fluidic circuit of the component 2, ideally, to optimise hydrodynamic resistance, the radius of the fluidic channel in the substrate 1 and the radius of the fluidic channel in the component 2 will be identical. However, it may prove necessary to limit the flow of material that occurs during sealing of the component 2 to the substrate 1, as this flow could otherwise block the fluidic aperture 12. To this end, as illustrated in FIGS. 4A and 4B, substrate-side, a chamfer 120 may be produced in the aperture (FIG. 4A), or around this aperture, by creating a concentric channel 121 (FIG. 4B) of suitable dimensions. For a chamfer 120, these dimensions may be defined by the following relationship:

Vd=π×x²/2×tan(y)×(2r+x×tan(y))

in which:
x corresponds to the height (in μm) of the chamfer to be produced;
y corresponds to the angle (in degrees) of the chamfer;
Vd corresponds to the volume of polymer of the substrate that flows during sealing and therefore that is to be removed by virtue of the presence of the chamfer (i.e. to the volume of all of the pads 24 encircling the aperture 12);
r corresponds to the radius of the fluidic channel.

As a variant of the chamfer, it is possible to envisage the creation of a right draft in the aperture 12, or even of a draft outside of a ring of pads 24 encircling the aperture.

E3: fastening of the component to the substrate is finalized. It will be noted that the seal-tightness is obtained without provision of means, such as seals, for ensuring seal-tightness, or of a substance such as an adhesive, solvent or equivalent.

Various trials have been carried out in order to validate the manufacturing process of the invention.

To take into account the characteristics of the micro-fluidic circuit of the substrate, various parameters of the component may be adjusted:
the number of lines of pads (around the aperture of the circuit, with a view to ensuring seal-tightness, and on the perimeter of the component, with a view to increasing its mechanical adhesion to the substrate): for example, 5 to 10 lines may be used;
the arrangement of the pads from one line to the next (aligned or staggered);
the distance separating the lines of pads from the aperture, which is for example comprised between 100 μm and 200 μm;

With reference to FIG. 5, trials have been carried out with substrates each comprising a micro-fluidic circuit having one of the following three configurations:
a aperture 12 of circular cross section opening onto the upper face of the substrate (configuration C1);
two apertures 120, 121 of circular cross section, each independently opening onto the upper face of the substrate (configuration C2);
a channel 122 recessed into the upper face of the substrate and forming an imprint in this face (configuration C3).

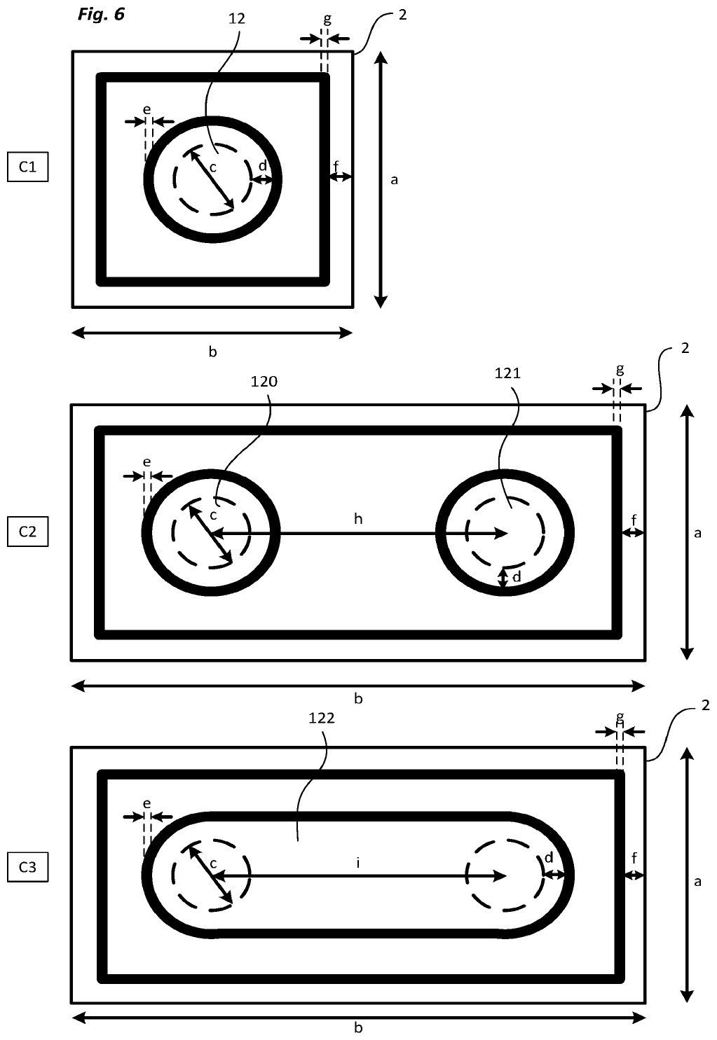

Starting with these various substrate configurations, FIG. 6 illustrates the various parameters that it is possible to adjust to ensure a seal-tight seal to the substrate in question (configuration C1, C2 or C3).

In these configurations, as may be seen, the following adjustment parameters may be adjusted:

(a) width of the component,
(b) length of the component,
(c) diameter of the fluidic aperture to be sealed, provided on the substrate,
(d) spacing between the pads produced on the component and the location of the aperture produced in the substrate,
(e) width of the strip of pads present on the component (it depends on the spacing d, on the diameter and on the number of pads) placed in a ring on the perimeter of the fluidic aperture,
(f) spacing between the edge of the component and the ring of pads,
(g) width of the strip of pads used in the ring provided to increase mechanical adhesion,
(h) spacing between two fluidic apertures (in the case of configurations C2 and C3),
(i) length of the fluidic channel (in the case of configuration C3).

Depending on the configuration, i.e. C1, C2 or C3, the component is of square shape and of 4×4 mm size, or rectangular and of 4×8.35 mm size.

Depending on these adjustment parameters, a plurality of component architectures may be provided in order to allow a seal-tight seal of the component to the substrate, for the various configurations (C1 to C3) of the substrate.

It will be noted that these adjustment parameters are to be taken into account, whatever the configuration of the micro-fluidic circuit of the substrate.

Seal-tightness was then measured for various substrate+component architectures, by injecting a fluid into the micro-fluidic circuit of the substrate at a given pressure (at least up to 1 bar).

It will also be noted that the addition of electrical functions remains compatible with the various embodiments. In this case, one or more pads 240 of the component comprise at least one conductive portion the role of which is to electrically connect to an electrical connection point of the substrate and to ensure electrical linkage of the electrical circuit of the substrate and of an electrical circuit of the component.

It will be understood from the above that the invention has many advantages, among which:
easy and rapid manufacture, possibly using equipment that already exists;
solution that allows a seal-tight fluidic connection to be obtained between the substrate and component, without provision of material or substance;
solution that also allows electrical connections between two circuits to be managed;
solution that allows the total number of hybridization steps to be decreased;
simultaneous management of a high number of capillary tubes and/or electrical contacts (high density);
irreversible hybridization solution;
solution that allows the components hybridized with the substrate 1 to be simplified via integration of the fluidics into the substrate 1 alone (configuration C3 above).

1. A process for manufacturing a micro-fluidic device, said device comprising a substrate made of thermoplastic polymer having a face called the upper face and a first micro-fluidic circuit that comprises at least one aperture that opens onto said upper face, and a component bearing pads arranged to become anchored in said substrate on the periphery of said aperture, said process being wherein said process includes the following steps:
heating so that the anchoring pads of the component reach a temperature at least equal to the glass-transition temperature of the substrate;
fastening the component to the substrate by embedding then anchoring its pads in the substrate.

2. The process according to claim 1, wherein said process includes a prior step of creating holes in the substrate, these holes each being configured to receive one separate anchoring pad of the component, with a view to facilitating the embedment of each anchoring pad of the component in the fastening step.

3. A micro-fluidic device comprising a substrate made of thermoplastic polymer having a face called the upper face and a first micro-fluidic circuit that comprises at least one aperture that opens onto said upper face, and a component bearing pads arranged to become anchored in said substrate on the periphery of said aperture, wherein said device is obtained using the manufacturing process such as defined in claim 1.

4. The device according to claim 3, wherein the substrate is made of cyclic olefin copolymer.

5. The device according to claim 3, wherein the component is produced on a silicon-on-glass substrate.

6. The device according to claim 5, wherein the anchoring pads comprise at least one first anchoring pad made at least partially from metal.

7. The device according to claim 6, wherein the substrate comprises a first electrical circuit and in that the component comprises a second electrical circuit, said first anchoring pad being configured to make an electrical connection between the first electrical circuit and the second electrical circuit.

8. The device according to claim 6, wherein the metal is composed of copper or of an alloy of SnAg type.

9. The device according to claim 5, wherein the anchoring pads comprise one or more anchoring pads made of silicon.

10. The device according to claim 3, wherein the anchoring pads have at their free end a rounded dome or a planar face.

11. The device according to claim 3, wherein the substrate comprises holes that are each configured to receive one separate anchoring pad of the component, said holes being produced with a view to facilitating the embedment of each anchoring pad of the component.

12. The device according to claim 3, wherein the component is applied, via a face called the lower face, against the upper face of the substrate and sealed to the substrate by way of said anchoring pads, and wherein the component is sealed in order to close the aperture of the first fluidic circuit in a seal-tight manner, on the upper face of the substrate.

13. The device according to claim 12, wherein the aperture of the first fluidic circuit takes the form of a channel the upper side of which is closed by the lower face of said component.

14. The device according to claim 3, wherein the component comprises a second micro-fluidic circuit and wherein said component is positioned on the substrate in order to ensure a seal-tight fluidic link between the first micro-fluidic circuit of the substrate and the second micro-fluidic circuit of the component.

15. The device according to claim 14, wherein the second micro-fluidic circuit of the component comprises at least one micro-fluidic channel arranged to ensure a seal-tight fluidic link between two apertures of the first fluidic circuit.

16. The device according to claim 3, wherein the component also comprises at least one row of anchoring pads arranged to anchor in said substrate and placed to form a peripheral bead for consolidating the attachment of the component to the substrate.
